(19) United States
(12) Patent Application Publication
(10) Pub. No.: US 2007/0152241 A1
(43) Pub. Date: Jul. 5, 2007

(54) Gate Capacitor Having Horizontal Structure and Method for Manufacturing the Same

(76) Inventor: Jung Ho Ahn, Danyang-gun (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/612,586

(22) Filed: Dec. 19, 2006

(30) Foreign Application Priority Data
Dec. 29, 2005 (KR) 10-2005-0134197

(51) Int. Cl. H01L 27/10

(52) U.S. Cl. 257/202

(57) ABSTRACT

A gate capacitor having a horizontal structure and a method for manufacturing the same is provided. The gate capacitor having a horizontal structure can be formed on a semiconductor substrate and used as a MOS transistor. The gate capacitor includes at least two adjacent gate electrodes and a capacitor dielectric layer filled between the two gate electrodes. In this case, insulating spacers can be formed at a sidewall of the gate electrodes in which the capacitor dielectric layer is not formed. As the gate capacitors can be used as a MOS transistor, a gate insulating layer can be formed between the two gate electrodes and the semiconductor substrate.

### RELATED APPLICATION(S)

This application claims the benefit under 35 USC § 119(e) of Korean Patent Application No. 10-2005-0134197 filed Dec. 29, 2005, which is incorporated herein by reference in its entirety.

### FIELD OF THE INVENTION

The present invention pertains to a capacitor of a semiconductor device. More particularly, the present invention pertains to a gate capacitor and a method for manufacturing the same, capable of using a gate electrode of a MOS transistor as an electrode of the capacitor.

### BACKGROUND OF THE INVENTION

With the development of high integration technologies for semiconductor devices, semiconductor devices including logic circuits having analog capacitors integrated thereon have been developed. Analog capacitors used in a logic circuit (for example, a CMOS logic circuit), are mainly divided into a polysilicon/insulator/polysilicon (PIP) type capacitor or a metal/insulator/metal (MIM) type capacitor.

The PIP capacitor has been widely used for the purpose of noise prevention and frequency modulation in an analog device. Since the lower electrode and the upper electrode of the PIP capacitor are fabricated by using multi-crystalline silicon which is often used as the gate electrode material of a logic transistor, the PIP capacitor can be manufactured through relatively simple processes.

In contrast, since the MIM capacitor must be formed with two or more metal layers used as capacitor electrodes, the manufacturing process for the MIM capacitor is complicated, and the capacitance per unit area is lower than that of the PIP capacitor. However, since the MIM capacitor has a stable temperature constant or a stable voltage constant, which represent variation of capacitance according to the temperature or the voltage, as compared with that of the PIP capacitor, the MIM capacitor is typically used for analog products requiring precise control of capacitance.

Generally, capacitance is controlled by using a gate oxide layer capacitor and either a PIP capacitor or MIM capacitor. However, in contrast to a metal-oxide-silicon (MOS) type capacitor or a junction capacitor, the PIP capacitor or the MN capacitor is independent from a bias voltage, so high precision is required for controlling the PIP capacitance or the MIM capacitance.

In addition, the gate oxide layer capacitor employs gate oxide layer capacitance formed between a multi-crystalline silicon gate and a silicon gate. However, if several gate oxide layer capacitors are to be simultaneously used, since the capacitors are connected to each other through a silicon substrate, it is difficult to design the capacitors. In addition, the capacitors are restrictedly used only when mass storage capacitance is required.

### BRIEF SUMMARY

Accordingly, an object of embodiments of the present invention is to provide a gate capacitor having a horizontal structure, which can be serially connected between gates so that it is easy to design the gate capacitor.

Another object of embodiments of the present invention is to provide a method for manufacturing a gate capacitor having a horizontal structure, capable of simplifying a manufacturing process as compared with that of a conventional capacitor.

Yet another object of embodiments of the present invention is to provide a method for manufacturing the gate capacitor while fabricating a MOS transistor without performing an additional process.

To achieve these objects and other advantages and in accordance with the purpose of the invention as embodied and broadly described herein, there is provided a gate capacitor including a plurality of gate electrodes formed on a semiconductor substrate in a row; and an insulating layer formed between the gate electrodes. The insulating layer can form the capacitor dielectric layer between electrodes.

According to another aspect of the present invention, there is provided a method for manufacturing a gate capacitor, the method including the steps of (1) forming a plurality of gate electrodes on a semiconductor substrate in parallel, (2) depositing a first insulating layer on the semiconductor substrate formed with the gate electrodes, (3) depositing a second insulating layer on the first insulating layer, (4) depositing a third insulating layer on the second insulating layer; and (5) removing the first insulating layer, second insulating layer, and third insulating layer to expose upper parts of the gate electrodes and form a spacer on a sidewall of a gate electrode.

In a preferred embodiment, the first insulating layer, second insulating layer, and third insulating layer can be removed through a plasma etching process.

In an embodiment, the thickness of the first insulating layer portion filling gaps between adjacent gate electrodes is equal to or greater than thickness of the gate electrode.

In yet another preferred embodiment the first insulating layer and the third insulating layer include oxide layers, and the second insulating layer includes a nitride layer.

According to still another aspect of the present invention, there is provided a method for manufacturing a gate capacitor, the method including the steps of (a) forming two or more gate electrodes in a row, (b) forming a first dielectric layer on the two or more gate electrodes such that a portion of the first dielectric layer fills in a gap between adjacent gate electrodes of the two or more gate electrodes, and (c) spacer-etching the first dielectric layer formed in a remaining area except for the portion of the first dielectric layer filling the gap between adjacent gate electrodes, thereby forming a spacer at one sidewall of each of two of the two or more gate electrodes.

In a preferred embodiment, a first insulating layer and a second insulating layer can be sequentially formed on the first dielectric layer after step (b), such that in step (c), the first insulating layer and the second insulating layer are spacer-etched with the first dielectric layer to form a spacer having a triple-layer structure at the one sidewall of each of the two gate electrodes.

### BRIEF DESCRIPTION OF THE DRAWINGS

FIGS. 1 to 4 are sectional views showing a method for manufacturing a gate capacitor having a horizontal structure according to an embodiment of the present invention.

### DETAILED DESCRIPTION OF THE PREFERRED EMBODIMENTS

Hereinafter, a gate capacitor having a horizontal structure and a method for manufacturing the same according to a preferred embodiment of the present invention will be described with reference to accompanying drawings.

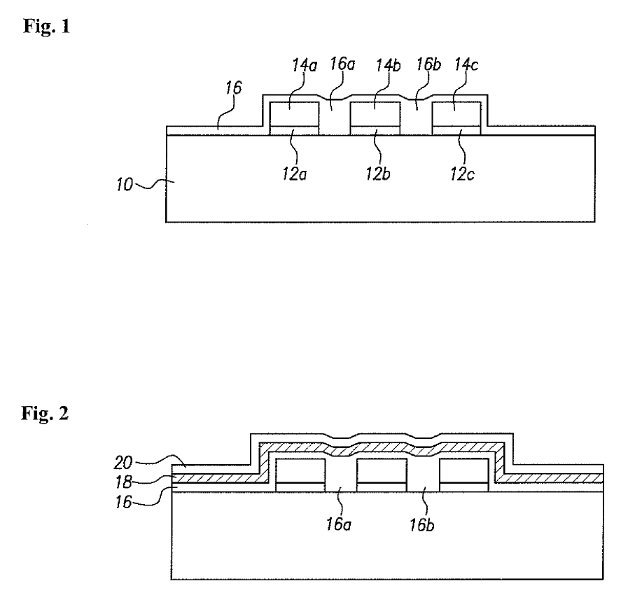

As shown in FIG. 1, gate oxide layers 12a, 12b, and 12c and multi-crystalline silicon gate electrodes 14a, 14b, and 14c can be formed on a silicon semiconductor substrate 10. Source and drain extension areas can be formed on active areas of the semiconductor substrate 10. Here, the source and drain extension areas for gate electrodes 14a, 14b, and 14c can be formed in active areas (not shown) in front of and behind the cross-section of FIG. 1. In an embodiment, the gate oxide layers 12a, 12b, and 12c, the gate electrodes 14a, 14b, and 14c, and the source drain extension areas can constitute three adjacent MOS transistors. In a preferred embodiment, the formation of a gate capacitor incorporating the gate oxide layers and the gate electrodes can be formed during the respective processes for forming MOS transistors during a manufacturing process.

Generally, after forming the gate oxide layers and the gate electrodes, a gate spacer is formed. Hereinafter, a process of forming a gate spacer having a triple-layer structure including oxide-nitride-oxide layers will be described according to an embodiment of the present invention. The gate capacitor having a horizontal structure according to the present invention can be formed during formation of the gate spacer.

Referring again to FIG. 1, after forming the gate oxide layers and the gate electrodes, a chemical vapor deposition (CVD) process can be performed to form an oxide layer 16. In one embodiment, oxide layer 16 can be a tetra ethyl ortho silicate (TEOS) film.

In a preferred embodiment, the oxide layer 16 can be formed to a thickness such that the oxide layer 16 sufficiently fills in gaps between adjacent gate electrodes.

The portions 16a and 16b of the oxide layer 16 that fill in the gaps between the gate electrodes 14a, 14b, and 14c can be used as capacitor dielectric layers, which will be described later. In a specific embodiment, the thicknesses of the oxide layer portions 16a and 16b are equal to or greater than thickness of the gate electrodes 14a, 14b, and 14c such that portions 16a and 16b at least completely fill the gaps between adjacent gate electrodes. By at least completely filling in the gaps between adjacent gate electrodes, a first insulating layer 18, which will be described later, can be prevented from being deposited in the gaps between the gate electrodes 14a, 14b, and 14c.

As can be understood from FIG. 1, since the neighboring gate electrodes 14a, 14b, and 14c are used as capacitor electrodes, serial gate capacitors can be formed.

Next, as shown in FIG. 2, in order to form the gate spacer having a tripe-layer structure, a first insulating layer 18 and a second insulating layer 20 can be sequentially formed on the oxide layer 16.

In one embodiment the first insulating layer 18 includes a silicon nitride layer, and the second insulating layer 20 includes an oxide layer.

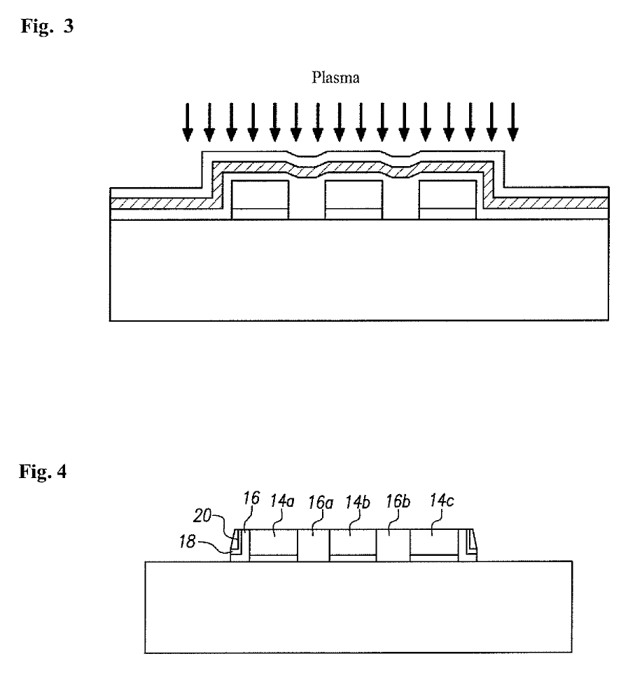

Then, as shown in FIG. 3, a spacer etching process can be performed with respect to the oxide layer 16, the nitride layer 18, and the oxide layer 20 formed on the semiconductor substrate 10.

In an embodiment of the spacer etching process, plasma of inert gases such as helium (He), neon (Ne), or argon (Ar) may be used.

In a preferred embodiment, the oxide layers 16a and 16b buried between the gate electrodes can be left unetched by adjusting an etching target during the spacer etching process.

As shown in FIG. 4, a gate spacer having a triple-layer structure including the oxide layer 16, the nitride layer 18, and the oxide layer 20 can be formed through the spacer etching process at sidewalls of the gate electrodes 14a and 14c.

Referring to FIG. 4, two capacitors, the first capacitor including first gate electrode 14a and second gate electrode 14b with dielectric layer 16a therebetween and the second capacitor including second gate electrode 14b and third gate electrode 14c with dielectric layer 16b therebetween can be serially connected by the shared second gate electrode 14b.

As described above, the two gate capacitors having the horizontal structure can be formed in the process of forming the gate spacer.

According to an embodiment of the present invention, the process of forming the two gate capacitors from the three gate electrodes is described. However, it is generally well known to those skilled in the art that the subject matter of the present invention is not limited to the number of the gate electrodes.

An embodiment of the present invention can be summarized as follows:

First, a plurality of gate electrodes can be formed on a semiconductor substrate in parallel.

A plurality of insulating layers can be sequentially deposited on the semiconductor substrate formed with the gate electrodes. In an embodiment, a first insulating layer of the plurality of insulating layers can have a thickness such that gaps between adjacent gate electrodes of the plurality of gate electrodes are at least completely filled to the height of the gate electrodes.

Next, a plasma etching process can be performed until upper parts of the gate electrodes are exposed.

As described above, the manufacturing process of the gate capacitor having the horizontal structure according to embodiments of the present invention can remarkably reduce process steps, as compared with the manufacturing process for a PIP capacitor or a MIM capacitor.

In addition, since the gate capacitors having a horizontal structure according to embodiments of the present invention are serially connected through the gate electrodes, it is easy to design and adjust the capacitance of the gate capacitor when compared with a conventional gate oxide layer capacitor.

While the invention has been shown and described with reference to certain preferred embodiments thereof, it will be understood by those skilled in the art that various changes in form and details may be made therein without departing from the spirit and scope of the invention as defined by the appended claims.

I claim:

1. A gate capacitor comprising:
a plurality of gate electrodes formed on a semiconductor substrate in a row; and
an insulating layer formed between the plurality of gate electrodes, wherein the insulating layer forms a capacitor dielectric layer for adjacent gate electrodes of the plurality of gate electrodes.

2. A method for manufacturing a gate capacitor, the method comprising:
forming a plurality of gate electrodes on a semiconductor substrate in parallel;
depositing a first insulating layer on the semiconductor substrate including the plurality of gate electrodes;
depositing a second insulating layer on the first insulating layer;
depositing a third insulating layer on the second insulating layer; and
removing the first insulating layer, second insulating layer, and third insulating layer until upper parts of the plurality of gate electrodes are exposed.

3. The method according to claim 2, wherein removing the first insulating layer, second insulating layer, and third insulating layer comprises performing a plasma etching process.

4. The method according to claim 2, wherein the first insulating layer is deposited at a thickness capable of at least completely filling gaps between adjacent gate electrodes of the plurality of gate electrodes.

5. The method according to claim 2, wherein the first insulating layer and the third insulating layer comprise oxide layers, and the second insulating layer comprises a nitride layer.

6. A method for manufacturing a gate capacitor, the method comprising the steps of:
(a) forming MOS transistors on a semiconductor substrate, wherein two or more gate electrodes of the MOS transistors are formed in a row;
(b) forming a first dielectric layer on the two or more gate electrodes such that a portion of the first dielectric layer fills in a gap between adjacent gate electrodes of the two or more gate electrodes; and
(c) spacer-etching the first dielectric layer to form a spacer at one sidewall each of two gate electrodes of the two or more gate electrodes, wherein the portion of the first dielectric layer that fills in the gap between adjacent gate electrodes remains.

7. The method according to claim 6, further comprising sequentially forming a first insulating layer and a second insulating layer on the first dielectric layer after step (b), and spacer-etching the first insulating layer and the second insulating layer with the first dielectric layer in step (c) such that a spacer having a triple-layer structure is formed at the one sidewall of each of the two gate electrodes.
